(19) United States
(12) Patent Application Publication
(10) Pub. No.: US 2004/0125965 A1
(43) Pub. Date: Jul. 1, 2004

(54) Method and apparatus for providing background audio during a communication session

(76) Inventors: William Alberth JR., Crystal Lake, IL (US); Louis Vannatta, Crystal Lake, IL (US)

Correspondence Address: VEDDER PRICE KAUFMAN & KAMMHOLZ, 222 N. LASALLE STREET, CHICAGO, IL, 60601, US

(21) Appl. No.: 10/330,635

(22) Filed: Dec. 27, 2002

(51) Int. Cl. H03G 3/00; H04B 3/00

(52) U.S. Cl. 381/77; 381/61

(57) ABSTRACT

A method and apparatus, locally inserts non-noise background audio information (104), such as music or other suitable information, as comfort audio information with other audio information (110), such as voice, to produce a combined audio signal (112) containing non-noise comfort audio. The combined audio signal (112) is transmitted over a communication channel such as wireline or wireless communication channel during a communication session or output locally over a speaker on a user device. The method and apparatus may locally insert non-noise background audio information (104) by selecting stored non-noise background audio information (104) from memory (102) local to a sending device (100) or selecting real time audio, such as an audio stream from a live broadcast as received by a radio, cable or television tuner.

### FIELD OF THE INVENTION

Invention relates generally to audio communication methods and systems, and more particularly to methods and apparatus for providing background audio during a communication session.

### BACKGROUND OF THE INVENTION

Audio communication systems such as wireline telephone systems, wireless cellular systems, video teleconferencing systems, or any other suitable audio systems, may provide comfort noise as background information during a telephone call, or meeting so that users can audibly detect that a connection is present when no one is speaking For example, cellular communication systems are known that insert comfort noise (i.e. white noise) during a call, which is typically added at all times during a communication session. Such comfort noise is not a tone or otherwise intelligible information but is typically white noise or other noise. As such, a mobile or non-mobile voice device may include a mixer that mixes, for example, voice information with white noise and pass it through a vocoder to be transmitted via a wireline network or wireless network. Similarly, such mixers and vocoders may be located in a network element and may also be used if desired to inject white noise during a telephone call. Such comfort noise, provides some background audio, and can indicate that a call is still in progress even though the parties on the call are not speaking. However, the white noise is typically is not selectable by a user nor is it intelligible to a listener, since it is noise. Also, the background noise can be so low that parties to a call cannot distinguish between the sounds of the other party or the sounds of a dropped call.

Telephone systems are also known that play, for example, background music when a caller is placed on hold. However, the background music is not typically inserted when the parties are speaking and is not typically selectable by a calling party or sender of the audio or by a party receiving the call.

In addition, new communication devices such as cellular telephones, PDA's, laptop devices, internet appliances and desktop computing devices include music players such as DVD players, MP3 players, MIDI file players and other audio playing mechanisms. However, to the extent such devices provide background noise during an audio communication, they typically provide white noise or other noise that is not intelligible to a listener or selectable.

### BRIEF DESCRIPTION OF THE DRAWINGS

The present invention is illustrated by way of example and not limitation in the accompanying figures, in which like references numerals indicate similar elements, and in which:

FIG. 1 is a block diagram illustrating one example of a device in accordance with one embodiment of the invention that provides non-noise background audio information inserted with other audio information during a communication session in accordance with one embodiment to the invention;

FIG. 2 is a flowchart illustrating one example of a method for providing background audio during a communication session in accordance with one embodiment of the invention;

FIG. 3 is a flowchart illustrating one example of a method for providing background audio during a communication session in accordance with one embodiment of the invention;

FIG. 4 is a block diagram illustrating in more detail, one example of a device in accordance with one embodiment to the invention;

FIG. 5 is a flowchart illustrating one example of a method for providing background audio during a wireless communication session in accordance with one embodiment of the invention; and

FIG. 6 is a flowchart illustrating one example of a method for providing background audio during a communication session in accordance with one embodiment of the invention.

### DETAILED DESCRIPTION OF THE PREFERRED EMBODIMENT

Briefly, a method and apparatus, locally inserts non-noise background audio information, such as music or other suitable information, as comfort audio information with other audio information, such as voice, to produce a combined audio signal containing non-noise comfort audio. The combined audio signal is transmitted over a communication channel such as wireline or wireless communication channel during a communication session or output locally over a speaker on a user device. The method and apparatus may locally insert non-noise background audio information by selecting stored non-noise background audio information from memory local to a sending device or selecting real time audio, such as an audio stream from a live broadcast as received by a radio, cable or television tuner.

In one example, the non-noise background audio information is user definable and selectable. Sender identification (ID) data such as a caller's telephone number, url, or email address can be used to select a particular song for example that is played while a telephone conversation is being carried out by the sending party and a receiving party. Similarly, receiver ID data, such as receiving party's telephone number, url, or email address obtained via a phone book entry in a cellular phone, PDA, or other suitable device may be used to select particular non-noise background audio information based on the receiver ID data when a call is initiated. For example, when a user places a phone call, the phone may insert output from an MP3 file or other audio source, with a user's voice as uplink audio. The file chosen is dependent on who the call is placed to. When the user answers a call, the non-noise background audio information is added to the received downlink voice information and the file is chosen dependent on the caller ID of the sender.

In another embodiment, since the feature may increase current drain of a mobile device because more uplink information is being sent, the local insertion of non-noise background audio information may be controlled and stopped, if for example, an output power exceeds a threshold or if a system capacity is being approached. In addition, the non-noise background audio information may be played back locally to a user as long as a call is active, for example, without adding the non-noise background audio information to voice information being sent out of the device. This may give a user feedback that a call is in process without the user needing to look at the display.

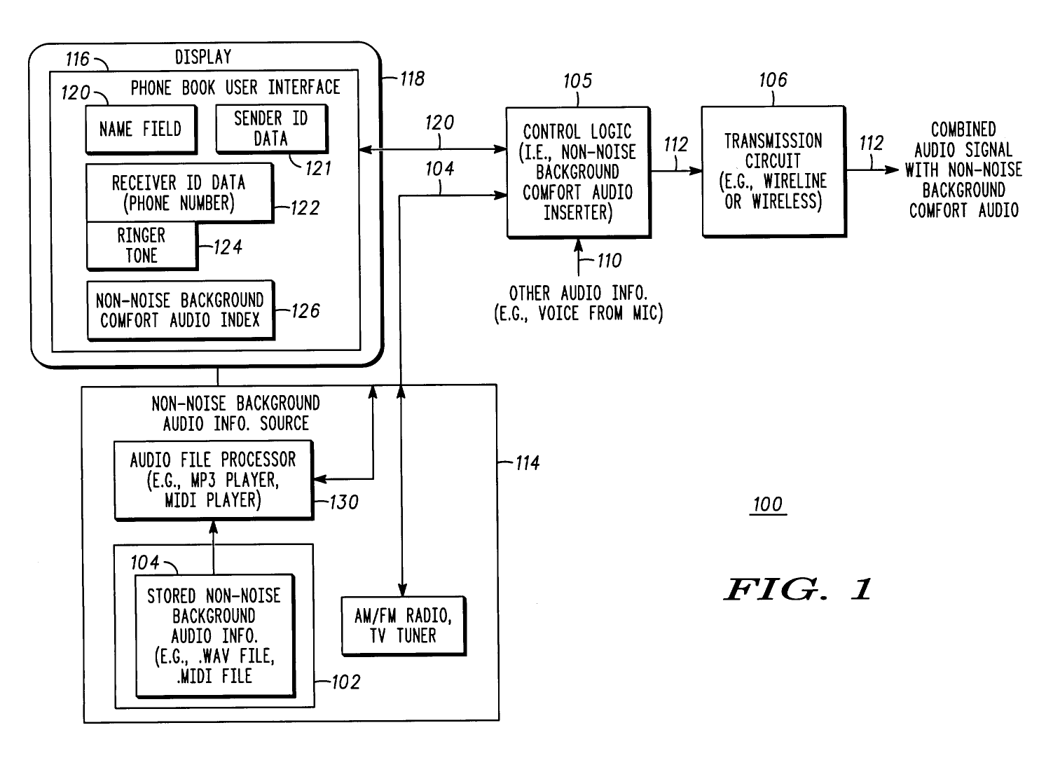

FIG. 1 illustrates a device 100 such as cellular telephone, PDA, internet appliance, laptop device, desktop device, or any other suitable device, and includes memory 102 containing stored non-noise background audio information 104, such as music files including but not limited to MP3 files, WAV files, MIDI files, or any other suitable form of non-noise background audio information. Non-noise as used herein refers to audio that is intelligible by user such as music or other intelligible audio. The device 100 also includes control logic 105 and transmission circuit 106. Control logic 105 may be any suitable hardware, software or firmware or any suitable combination thereof including, but not limited to, one or more DSP's, discreet logic circuits, processors, microcontrollers, CPU's, state machines, or any other suitable structure. The transmission circuit 106 may be any suitable non-wireless or wireless transmission circuit including, but not limited to an RF transmission circuit, a modem, an infra-red transmission circuit or any other suitable transmission circuit.

The control logic 105 is operably coupled to the memory 102 and receives non-noise background audio information 104 from the memory 102 or other non-noise background audio information source 114, and also receives other audio information 110 such as voice from a microphone. The control logic 105 locally inserts the non-noise background audio information 104 as background comfort audio information with the other audio information 110 to produce a combined audio signal 112. The transmission circuit 106 is operatively coupled to transmit the combined audio signal 112 over a channel during a communication session.

The non-noise background audio information 104 may be provided by any suitable non-noise background audio source. As shown, non-noise background audio information source 114 may include one or more different types of non-noise background audio information sources. By way of example and not limitation, a DVD player may provide music or other audio that serves as the non-noise background audio information 104. A television receiver that receives live broadcasts or AM/FM radio receiver may also provide a stream of non-noise background audio information 104 for the control logic 105.

The device 100 also includes a user interface 116, in this example a graphic user interface on a display 118. However, any suitable interface may be used. For purposes of illustration only and not limitation, the user interface 116 will be described as a phonebook interface. Such an interface is common in mobile devices, such as telephones, PDAs or non-mobile devices such as desktop devices. The phonebook interface 116 includes in this example a name field 120, a receiver ID field 122 (such as a phone number field), a ringer tone field 124 and a non-noise background comfort index field 126. It will be understood by one of ordinary skill in the art that only one or more of these fields need to be used. In this example, the name field 120 is populated by the name of a receiver of a telephone call or other recipient. The phone number field 122 is populated with for example a telephone number, url, email address, or any other suitable receiver identification (ID) data. The ringer tone field 124 may be populated with one of a plurality of selectable ringer tones to be played when a telephone call is received.

The user interface 116 controls the linking of, for example, receiver ID data 122 and/or sender ID data to the stored non-noise background audio information 104. This may be accomplished in any suitable manner, for example through database linking or other suitable mechanism. In this example, the non-noise background comfort audio index field 126 contains user selected data that points to a stored audio file, which serves as the stored non-noise background audio information. The non-noise background audio indexing may be done for example through a pull down menu with the names of prestored audio files that a user may select and associate with the receiver ID data 122. It will be recognized that the name field 120 may also be considered receiver ID data since any identification information that identifies a receiver and associates the receiver with stored non-noise background audio information is suitable. In one embodiment the non-noise background audio information, as noted above, is music information such as a .WAV file or MP3 file and the other information 110 is voice information being spoken through a microphone on the device or through a microphone plugged into the device.

The stored non-noise background audio information 104 may include a plurality of selectable prestored audio elements such as the aforementioned audio files. As noted above, the non-noise background audio information 104 may also be information from a DVD, CD, or other storage mechanism or from a buffer that receives live broadcast information.

As shown in this example, the control logic 105 also provides the user interface 116 as represented by arrow 120. However, it will be recognized that a different circuit or a set of circuits may provide an interface if desired.

The non-noise background audio information 104 may also be linked to sender ID data, such as a telephone number of a sending device or user, or sender name or other suitable ID data, so that for example each time the device initiates a telephone call a particular song is played as non-noise background information. Accordingly, the user interface 116 may also present an interface to receive sender ID data 121 and to associate (e.g., link) non-noise background audio information, such as an MP3 file with a particular sender telephone number or name or other suitable sender identification data. Hence, a customized non-noise comfort audio provision is provided via a user interface to allow selection and control by user as to which music is played as background music and to select different background music for different parties that are called.

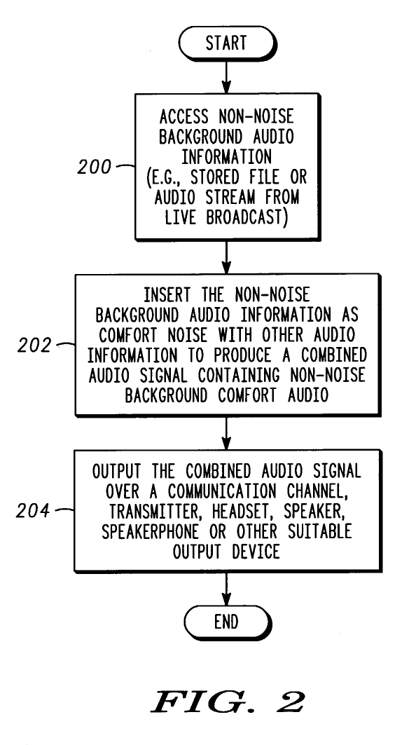

FIG. 2 illustrates one example of a method for providing background audio during a communications session, which begins in block 200 by accessing non-noise background audio information. This may be done for example by analyzing receiver ID data 120 or sender ID 121 data and identifying which audio file is linked with the particular receiver ID 120 data or sender ID 121 data and then activating the audio file processor 130 (FIG. 1) to play the appropriate file. Alternatively, accessing may include accessing a stream of live audio from a TV receiver, AM/FM radio receiver or other non-noise background audio information source. As such, accessing non-noise background audio information may include for example retrieving the stored non-noise background audio information 104 from memory local to a sending device or playing the retrieved information or otherwise obtaining real time audio such as audio stream from a live television link or AM/FM radio receiver. As shown in block 202, the method includes inserting non-noise background audio information 104 as comfort audio information with the other audio information 110 to produce a combined audio signal 112 containing non-noise background comfort audio. This may be done for example by mixing the non-noise background audio information 104 with the other information 110 as known in the art of combining audio information. Once combined, the method includes, as shown in block 204, outputting the combined audio signal (analog or digital). This may done in a number of ways such as by transmitting, such as by transmission circuit 106 over a communication channel during a communicating session, or by outputting the signal to a speaker, speakerphone, headset, car kit, or wireless headset. This may include for example sending the signal by a modem or a wireless transmitter circuit over a suitable communication channel, or outputting the combined audio signal during a communication session through a USB port or other output.

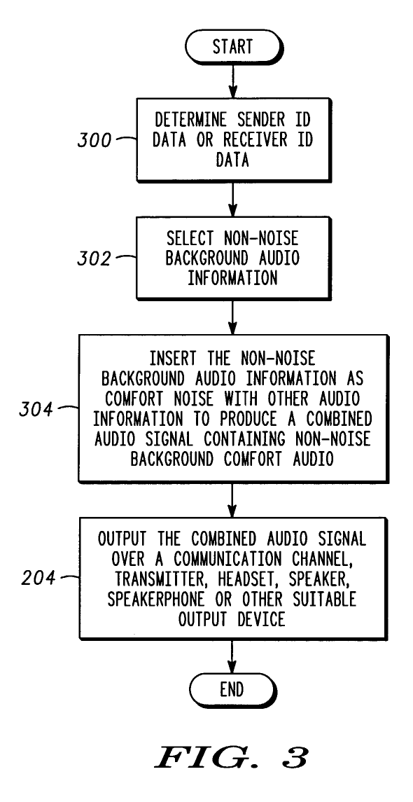

FIG. 3 illustrates another method for providing background audio during a communications session that includes, as shown in block 300, determining at least one of the sender ID data and receiver ID data. This may be determined for example when a user, in the case of a telephone application, dials a telephone number, which may serve as the receiver ID data. Alternatively, sender ID data may be determined for example from caller ID data when a call is received, or by a default setting so that every time any number is dialed, the same non-noise background audio information is combined with outgoing voice. Alternatively, the device may facilitate use by different senders and each sender may have their own ID stored in an identification database or other suitable location, which may be accessed upon the initiation of a telephone call for example. The sender ID data may be for example identification of a person that is initiating a call or ID of a calling device as such, a caller ID telephone number for example may be used as a sender ID in that instance. A sender ID or if a receiver ID is used to select the comfort background information, could also be an email address, url, or an IP address. The determination may be done by the control logic 105 or any other suitable circuit or process.

The method continues in block 302 by selecting the non-noise background audio information based on either the sender ID data, receiver ID data or both as determined in the previous step 300. For example, a specific file may be linked to a particular sender ID or recipient ID. The music file is then, as shown in block 304, locally inserted by the control logic 105 to be combined with other audio information. This is similar to block 202 in FIG. 2. The combined audio signal is then output as shown in 306. Either transmitted over a communication channel whether its wireline or wireless, or output to a speaker, speakerphone, car kit, headset, or wireless headset.

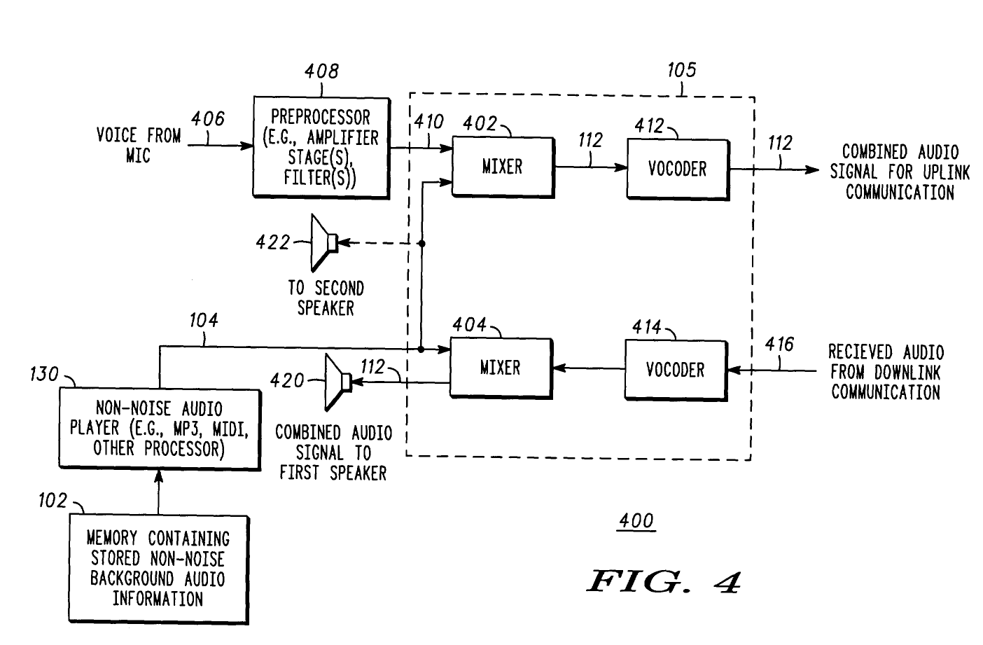

FIG. 4 illustrates in more detail, one example of a device 400, such as mobile wireless device wherein the control logic 105 is coupled to a wireless transmission circuit (not shown) and includes a first mixer 402 operably coupled to the memory 102 and operative to produce the combined audio signal 112. The first mixer 402 receives the non-noise background audio information 104 as output for example by an audio processor and also receives other audio information 410, in this example, voice information as received by a microphone in or coupled to device 400, shown as block 406. An audio pre-processor 408 processes the users voice using conventional techniques and passes the processed voice 410 to the first mixer 402. The output is the combined audio signal 112. The control logic 105 also includes a vocoder 412, which is operably coupled to an output of the first mixer 402 and is operative to code the combined audio signal for an uplink communication. The voice information 406 originates from the device 400 such as when a user talks into the microphone of the device.

The control logic 105 includes a second mixer 104 and a second vocoder 414. The second mixer 404 receives the non-noise background audio information 104 and also receives audio information from a down link communication (e.g., when the other party talks) indicated as 416. This may also include sender ID data such as caller ID data. The second vocoder 414 is operative to receive down link audio information 416. The second mixer 404 is operably coupled to the memory 102 and to an output of the second vocoder 414 and produces the combined audio signal 112 from the received down link information and the non-noise background audio information. This is then provided to a speaker in device 400 as shown as speaker 420. The presence of the comfort noise informs the user that the communication link is still present.

Alternately, a device 400 may also include a second speaker 422 which is operably coupled to receive the non-noise background audio which may be played for example so that the user knows that a communication session in progress even though the recipient is not talking. This way the user need not look at a screen to determine whether or not the telephone call is still connected. The non-background audio information may be stopped from being operative to speaker 422 when the call is dropped. This may be accomplished by for example the control logic 105 or any other suitable logic switching the signal not from the speaker or turning off the music playing device.

The mixers 402 and 404 and vocoders 412 and 414 may be any suitable mixers and vocoders as known in the act.

As shown, the non-noise background audio information 104 may be combined with voice information spoken by the user of the device 400 through mixer 402 and output as an uplink communication, or non-noise background audio information 104 may be added to down link audio by mixer 404 based on sender ID data. This diagram depicts adding analog non-noise to the audio stream, it should be obvious that other methods exist such as adding the non-noise to the audio stream in the digital domain. To avoid both devices added non-noise background, it may be desireable to include a menu function that allowed the user to deactivate the process for a call.

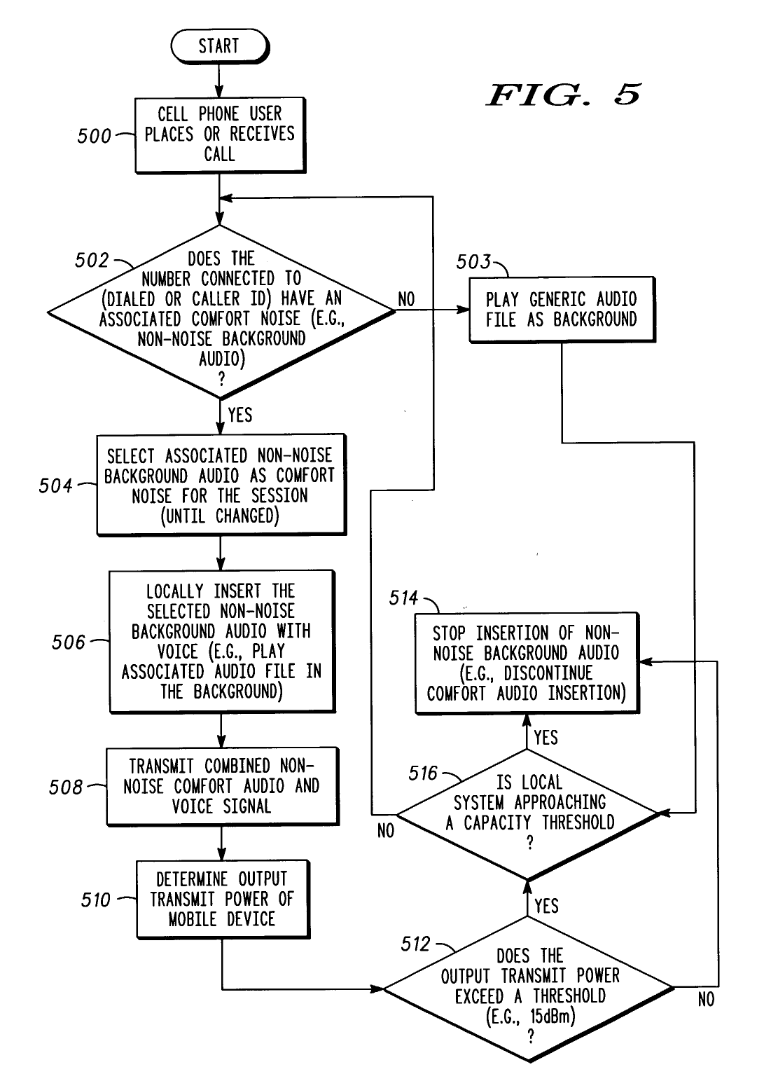

FIG. 5 is a flowchart illustrating in more detail another example of a method for providing background audio during a communication. In this example, it will be assumed that the device 400 is a cell phone or other suitable device with a cell phone capabilities. As shown in block 500 the method includes a cell phone user placing or receiving a telephone call. As shown in block 502 the method includes determining whether the number connected to, such as dialed, or caller ID if it is being received, has an associated comfort noise designation. In other words, a determination is made based on a sender ID data or receiver ID data as to whether or not non-noise background audio information has been associated with the identification data through default operation when the telephone is manufactured. As shown in block 503, if the number connected to does not have associated comfort noise assigned to it, generic audio is played as background audio.

As shown in block 504, the method includes selecting the associated non-noise background audio information as comfort noise for the session or at least it is changed for example by a user selecting a different music file for the session. As shown in block 506, after the appropriate music file has been selected, the method includes locally inserting the selected music file with the voice being received. As shown in block 508, the method includes transmitting the combined non-noise comfort audio and voice signal. Various control features are also advantageous depending on system criteria or device criteria. For example, as shown in block 510, the method includes determining, such as by the control logic, the output transmit power of the mobile device. This may be determined in any conventional manner. As shown in block 512, after determining an output transmit power level of the mobile device, the method includes determining whether the transmit power exceeds a threshold level. The threshold level may be set for example through a user interface or by default or by any other suitable mechanism. For example, if the transmit power exceeds for example 15 dBm, there may be an undesirable increase in current drain caused by transmitting comfort audio. Accordingly, the method includes stopping or turning off the insertion of comfort noise, by stopping the local insertion of the non-noise background information based on the determined output transmit power. This is shown in block 514. As such, only the voice information may be than transmitted by the device.

As shown in block 516, if the output transmit power does not exceed a threshold, the method includes determining if the local communication system to which the device is communicating is approaching a capacity threshold. For example, this may be determined by the device analyzing frame error rates, received signal quality levels, or any other suitable receiver metrics. The threshold may be set via an interface or controlled for example via a control channel if desired, or using any other suitable mechanism. This may also be determined based on the downlink power that the device is receiving or a message in the system overhead channel such as control channel. As such, the control logic will stop the local insertion of the non-noise background as comfort audio with the other audio in response to a capacity threshold of a communication system or subsystem.

In addition, if desired, the control logic may be responsive to a received message from a network element such as a control channel message that indicates to stop the local insertion of a non-noise background as comfort audio information, to allow the other audio information transmitted without the non-noise background. For example, this can facilitate network level control of whether non-noise background is inserted during a conversation. As such, a system operator may control a plurality of mobile devices as to whether not they are able to insert the non-noise background audio information during a conversation.

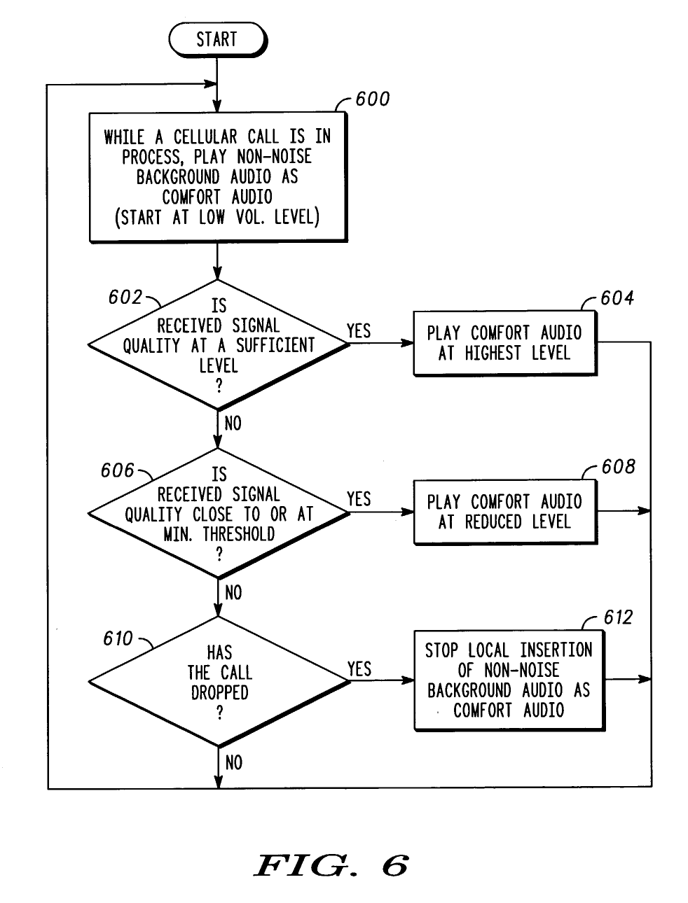

FIG. 6 is a flowchart illustrating another example of a method for providing background audio during a communication session. As shown in block 600, the method includes while a cellular call is in process, playing the non-noise background audio as comfort audio at for example a low volume level. As shown in block 602, the method includes determining if a received signal quality indication is at a sufficient level. Signal quality can be determined by RSSI (Received Signal Strength Indicator), Frame Erasure rate, bit error rate, sinad, pilot signal strength, or by other methods obvious to those skilled in the art. If it is at a sufficient level, as shown in block 604, the method includes playing the comfort audio (inserting non-noise background audio) at a higher volume level. However, as shown in block 606, if the received signal quality of the device is not at a sufficient level, then a determination is made as to whether the received signal quality is close to or at a minimum threshold. This may be done by the control logic comparing the received signal quality to a minimum threshold quality. If the received signal quality is close to or at a minimum threshold, the method includes as shown in block 608, playing the comfort noise audio at the reduced volume.

As shown in block 610, if the received signal quality is below an acceptable minimum threshold, the method includes determining whether the call is dropped. This may be determined in a conventional manner. If the call has been dropped, as shown in block 612, the method includes stopping local insertion of the non-noise background audio. The method then returns to block 600 to continue analyzing for the next call the received signal quality and making appropriate adjustments.

As illustrated, the above methods and apparatus, among other things, provide non-noise background audio information, as opposed to white noise, that is selectable by user and is also selectively modifiable based on for example who is calling a particular device or who is being called by a particular device. This can enhance a user's experience of any wireless, non-wireless, mobile or non-mobile device that communicates audio information. Other advantages will be recognized by those of ordinary skill in the art.

The above apparatus and methods, among other advantages, gate in broadcast information or other system information when, for example, a mobile device or other multimode receiving device is listening to a synchronization channel on a non-synchronized network such as a cellular network. Hence, the multimode receiving device, which also may have suitable transmitter stages, receives information from one system to a point where after the multimode receiving device switches to a different receiver and receives gated information from a different network. The multimode receiving device switches to a second receiver to receive gated information transmitted from a first wireless system (e.g. broadcast system) that was gated, such as by, for example, a network element, based on timing synchronization information from the second wireless system. As such, an onboard processor, plurality of processors or other suitable logic, need not process information from two differing systems at the same time. In addition, if propagation delays and multipath signals are being received by the multimode receiving device, the gated information at the broadcast network element is gated for a longer period of time to accommodate for the multipath delays. Other advantages will be recognized by those skilled in the art.

It should be understood that the implementation of other variations and modifications of the invention and its various aspects will be apparent to those of ordinary skill in the art, and that the invention is not limited by the specific embodiments described. It is therefore contemplated to cover by the present invention, any and all modifications, variations, or equivalents that fall within the spirit and scope of the basic underlying principles disclosed and claimed herein.

What is claimed is:

1. A method for providing background audio during a communication session comprising:
locally inserting non-noise background audio information as comfort audio information with other audio information to produce a combined audio signal containing non-noise background comfort audio; and
outputting the combined audio signal during a communication session.

2. The method of claim 1 wherein the combined audio signal is output to a transmitter for transmission over a communication channel.

3. The method of claim 1 wherein the combined audio signal is output to a speaker.

4. The method of claim 1 wherein the non-noise background audio information includes music information and wherein the other audio information is voice information and wherein the step of locally inserting the non-noise background audio information includes combining the music information with voice information.

5. The method of claim 1 including the step of accessing non-noise background audio information from at least one of memory local to a sending device and real time audio.

6. The method of claim 5 wherein the memory includes a plurality of pre-stored audio elements.

7. The method of claim 1 including:
determining at least one of: sender ID data and receiver ID data; and
prior to locally inserting the non-noise background as comfort audio information, selecting the non-noise background audio information in response to at least one of: the sender ID data and receiver ID data.

8. The method of claim 7 including providing a user interface to control linking of at least one of sender ID data and receiver ID data to locally stored non-noise background audio information.

9. The method of claim 1 including:
determining an output transmit power level of a mobile device;
stopping the local insertion of the non-noise background audio information as comfort audio information, based on the determined output transmit power, to allow the other audio information to be transmitted without the non-noise background audio information.

10. The method of claim 1 including:
stopping the local insertion of the non-noise background as comfort audio information to allow the other audio information to be transmitted without the non-noise background audio information in response to a capacity threshold of a communication system or subsystem.

11. The method of claim 10 wherein the capacity threshold is determined based on at least one of: a frame error rate determined by a mobile device that is locally inserting the non-noise background audio information as comfort audio information with other audio information and a downlink power level determined by the mobile device.

12. The method of claim 1 including, receiving a message indicating to stop the local insertion of the non-noise background as comfort audio information during uplink communication to allow the other audio information to be transmitted without the non-noise background audio information.

13. The method of claim 1 including decreasing a volume level of the non-noise background audio in the combined audio signal in response to a decrease in received signal quality.

14. A method for providing background audio during a communication session comprising:
determining at least one of: sender ID data and receiver ID data; and
selecting non-noise background audio information for insertion with voice information during a communication session in response to at least one of: the sender ID data and receiver ID data.

15. The method of claim 14 including
locally inserting-selectable non-noise background audio information as comfort audio information with the voice information to produce a combined audio signal containing non-noise background comfort audio, wherein the non-noise background audio information is music, by combining the music information with the voice information; and
transmitting the combined audio signal over a communication channel during a communication session.

16. The method of claim 15 including the step of accessing non-noise background comfort audio information from at least one of: memory local to a sending device and real time audio accessible by the sending device.

17. A device comprising:
memory containing stored non-noise background audio information;
control logic, operatively coupled to the memory, and operative to locally insert the non-noise background audio information as background comfort audio information with other audio information to produce a combined audio signal; and
a transmission circuit operatively coupled to transmit the combined audio signal over a channel during a communication session.

18. The device of claim 17 including a user interface to control linking of at least one of receiver ID data and sender ID data to the stored non-noise audio information.

19. The device of claim 17 wherein the non-noise background audio information is music information and wherein the other audio information is voice information and wherein the control logic combines the music information with voice information.

20. The device of claim 17 wherein the transmission circuit includes a wireless transmitter and wherein the control logic includes:
a mixer operatively coupled to the memory and operative to produce the combined audio signal, and
a vocoder, operatively coupled to the mixer, and operative to code the combined audio signal.

21. The device of claim 17 wherein the transmission circuit includes a wireless transmitter and wherein the control logic includes:
a first mixer operatively coupled to the memory and operative to produce the combined audio signal for an uplink communication,
a first vocoder, operatively coupled to an output of the first mixer, and operative to code the combined audio signal for an uplink communication;
a second vocoder, operative to receive downlink audio information; and
a second mixer, operatively coupled to the memory and to an output of the second vocoder that produces the combined audio signal from the received downlink audio information.

22. The device of claim 17 wherein the non-noise background audio information includes a plurality of selectable pre-stored audio elements.

23. The device of claim 17 wherein the control logic determines an output transmit power level of a mobile device and stops the local insertion of the non-noise background audio information as comfort audio information, based on the determined output transmit power, to allow the other audio information to be transmitted without the non-noise background audio information.

24. The device of claim 17 wherein the control logic is operative to stop the local insertion of the non-noise background as comfort audio information to allow the other audio information to be transmitted without the non-noise background in response to a capacity threshold of a communication system or subsystem.

25. The device of claim 17 wherein the control logic is responsive to a received message from a network element, indicating to stop the local insertion of the non-noise background as comfort audio information to allow the other audio information to be transmitted without the non-noise background.

26. A device comprising:
memory containing stored non-noise background audio information;
control logic, operatively coupled to the memory, and operative to control linking of at least one of receiver ID data and sender ID data, to the stored non-noise audio information as designated through a user interface, locally insert the non-noise background audio information as background comfort audio information with other audio information to produce a combined audio signal, and the control logic determines at least one of: sender ID data and a receiver ID data; and prior to locally inserting the non-noise background as comfort audio information, select the non-noise comfort audio information in response to at least one of: the sender ID data and receiver ID data;
a wireless transmission circuit operatively coupled to transmit the combined audio signal over a wireless channel during a communication session.

27. The device of claim 26 wherein the non-noise background comfort audio information is music information and wherein the other audio information is voice information and wherein the step of locally inserting the non-noise background audio information includes combining the music information with voice information.
